(19) United States
(12) Patent Application Publication
(10) Pub. No.: US 2006/0087326 A1
(43) Pub. Date: Apr. 27, 2006

(54) Resistive sensing element circuit

(76) Inventor: Robin Terence Albert Stevens, Lancing (GB)

Correspondence Address: IRA S. DORMAN, 330 ROBERTS STREET, SUITE 200, EAST HARTFORD, CT, 06108, US

(21) Appl. No.: 11/259,012

(22) Filed: Oct. 26, 2005

(30) Foreign Application Priority Data
Oct. 26, 2004 (GB) 0423718.6
Mar. 31, 2005 (GB) 0506493.6

(51) Int. Cl. G01R 27/26

(52) U.S. Cl. 324/680

(57) ABSTRACT

A resistive sensing element circuit arrangement includes first and second variable resistance sensing elements R1 and R2 connected in series to form a resistive sensing element set having a first centre connection, first and second fixed resistors Rb1 and Rb2 connected in series and having a second centre connection, and a differential amplifier having a positive input, a negative input and an output. When the variable resistance sensing elements R1 and R2 are inactive the voltage at the first centre connection is equal to the voltage at the positive input of the differential amplifier and when the variable resistance sensing elements are active the voltage at the output of the differential amplifier is proportional to an out-of-balance current that flows through a feedback resistor Rf multiplied by the value of the feedback resistor.

The invention relates to a resistance sensing element circuit such as may be used for the measurement of strain.

### DESCRIPTION OF PRIOR ART

The basic circuit used for the measurement of strain is the Wheatstone bridge, as it provides a simple means of measuring small changes in resistance with a high degree of accuracy. There are two methods of reading the signal generated by the strain gauges, either by differential voltage measurement or by reading the out-of-balance current. Before the 1970s the out-of-balance current was used in a conventional Wheatstone bridge circuit and was referred to as the deflection measurement system. Such a system was very successful for both static and dynamic measurements. The advent of instrumentation amplifiers and specially designed strain gauge amplifiers soon made the differential voltage measurement the international standard even though the voltage signal is very small and causes noise and environmental errors and even though the cabling and instrumentation are very expensive. A number of alternative methods have been proposed to alleviate the problems set out above, but there has never been a serious alternative to the Wheatstone bridge.

### OBJECT OF THE INVENTION

The present invention aims to provide an alternative arrangement for resistive sensing by measuring accurately the out-of-balance current and producing a large voltage signal for transmission purposes.

### SUMMARY OF THE INVENTION

According to the present invention there is provided a resistive sensing element circuit arrangement comprising:

first and second variable resistance sensing elements connected in series to form a resistive sensing element set having a first centre connection;

first and second fixed resistors connected in series and having a second centre connection;

a voltage supply having a positive voltage output connected to the free end of the first variable resistance sensing element and to the free end of the first fixed resistor and having a negative voltage output connected to the free end of the second variable resistance sensing element and to the free end of the second fixed resistor;

a differential amplifier having a positive input, a negative input and an output;

means connecting the first centre connection of the resistance sensing element set to the negative input of the differential amplifier;

means connecting the second centre connection of the series-connected fixed resistors to the positive input of the differential amplifier; and

a feedback resistor connected between the output and the negative input of the differential amplifier,

the arrangement being such that when the variable resistance sensing elements are inactive the voltage at the first centre connection of the first and second variable resistance sensing elements is set equal to the voltage at the positive input of the differential amplifier and when the variable resistance sensing elements are active the voltage at the output of the differential amplifier is proportional to an out-of-balance current that flows through the feedback resistor multiplied by the value of the feedback resistor.

The circuit arrangement may include a plurality of sets of first and second variable resistance sensing elements connected to the first centre connection.

The circuit arrangement may include a first further resistor connected in series between the positive voltage output of the voltage supply and the free end of the first variable resistance sensing element and a second further resistor connected between a point between the first further resistor and the free end of the first variable resistance sensing element and the output of the differential amplifier so as to provide a linearity correction when only the resistive sensing element connected to the positive voltage output of the voltage supply is active.

The circuit components other than the resistive sensing element set(s) and the voltage supply may be encapsulated into an epoxy-glass laminate Faraday cage.

The variable resistance sensing elements may be in the form of sensing elements that employ a change in resistance for measuring purposes.

The variable resistance sensing elements may be in the form of strain gauges. However the invention also applies to any resistive sensing element that relies on the change in resistance for its measurement, examples include platinum resistance thermometers, piezo-resistive sensors, magneto-resistive sensors and liquid level sensors.

The values of the variable resistance sensing elements may be substantially equal.

The values of the first and second fixed resistors may be substantially equal.

Thus the present invention provides a circuit in which the voltage at the output of the differential amplifier produces a current that flows through the feedback resistor, feeding current into the first centre connection of the first and second variable resistance sensing elements until the voltage at the first centre connection is equal to the voltage at the positive input of the differential amplifier. Consequently, the voltage at the output of the differential amplifier is proportional to the out-of-balance current that flows through the feedback resistor multiplied by the value of the feedback resistor.

For a better understanding of the present invention and to show more clearly how it may be carried into effect reference will now be made, by way of example, to the accompanying drawings in which:

### BRIEF DESCRIPTION OF THE DRAWINGS

FIG. 1 is a block schematic circuit of one embodiment of a resistive sensing element circuit according to the present invention, for the measurement of strain;

FIG. 2 is a block schematic circuit of another embodiment of a resistive sensing element circuit according to the present invention, again for the measurement of strain;

FIG. 3 is a block schematic circuit of a further embodiment of a resistive element sensing circuit according to the present invention, again for the measurement of strain; and

FIGS. 4a,4b and 4c illustrate a construction of a resistive sensing element circuit according to the present invention.

### DESCRIPTION OF PREFERRED EMBODIMENTS

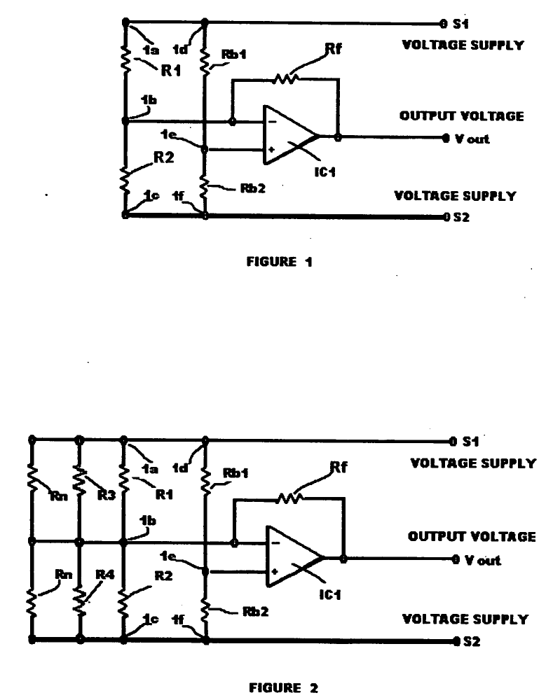

With reference to FIG. 1, a voltage supply at terminals S1 and S2 is connected across a resistive sensing element set R1 and R2 at respective terminals 1a and 1c, R1 and R2 preferably being of equal value under normal conditions. The voltage supply at terminals S1 and S2 is also connected across the two precision resistors Rb1 and Rb2 at respective terminals 1d and 1f, Rb1 and Rb2 preferably being of equal value. Terminals 1a and 1d are interconnected as are terminals 1c and 1f.

When the resistive sensing elements R1 and R2 are in a non-active condition, the reference voltage at terminal 1e is connected to the positive input of a differential amplifier IC1 whose output drives a feedback resistor Rf. The feedback resistor is also connected to the negative input of the differential amplifier IC1 so that the voltage at the negative input of the differential amplifier IC1 is equalised to the voltage at the positive input of the differential amplifier IC1 and the circuit is in a balanced condition with the voltage at the output equal to the balance voltage at the inputs. In this condition no current will flow through the feedback resistor Rf.

When one of the resistive sensing elements R1 and R2 is active, the voltage at terminal 1b will start to change. This in turn will cause to output voltage of the differential amplifier IC1 to change in the opposite direction, driving current through the feedback resistor Rf until the voltage at terminal 1b returns to its balance voltage. Consequently, the out-of-balance current flows through the feedback resistor Rf such that the change in output voltage equals the out-of-balance current multiplied by the value of the feedback resistor Rf.

That is, the voltage at the output of the differential amplifier IC1 produces an out-of-balance current that flows through the feedback resistor Rf and feeds into the centre connection 1b of the resistors R1 and R2 until the voltage at the connection 1b is equal to the voltage at the positive input of the differential amplifier IC1. Consequently, the voltage at the output of the differential amplifier IC1 is proportional to the out-of-balance current that flows through the feedback resistor Rf multiplied by the value of the feedback resistor.

The embodiment of FIG. 2 differs from that of FIG. 1 in that additional resistive sensing element sets R3 to Rn and R4 to Rn are provided with all their respective terminals connected to form a common resistive sensing element set to provide a larger out-of-balance current signal or an average measurement should that be required. The common terminals of the resistive sensing elements can be considered to be in a star arrangement, centered on terminal 1b.

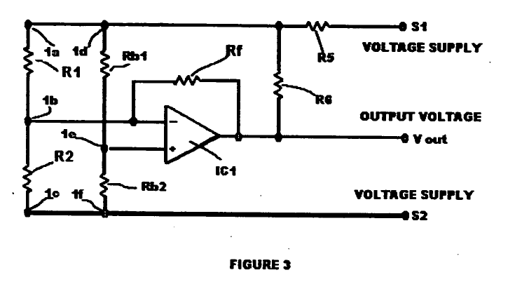

The embodiment of FIG. 3 differs from that of FIG. 1 in that two additional resistors R5 and R6 are provided. One terminal of resistor R5 is connected to the positive voltage supply at terminal S1, while the other terminal of resistor R5 is connected to terminals 1a and 1d. One terminal of resistor R6 is connected to the output of the differential amplifier IC1, while the other terminal of resistor R6 is connected to terminals 1a and 1d. When the circuit of FIG. 1 is used with resistor R1 as the only active sensing element it produces a non-linear out-of-balance current. However, in the circuit of FIG. 3 resistor R5, together with resistor R6, corrects the non-linear signal by modulating the voltage at terminals 1a and 1d.

An example of the typical resistor values for a 120 Ohm STC strain gauge with a gauge factor of 2, for a +/−20,000 micro-strain circuit, with R2=120 Ohms, Rf=2.5 KOhms, Rb1=Rb2=5.62 KOhms, R6=1.5 KOhms, R5=154 Ohms, S1=4.096 volts and S2=0 volts, then the voltage at terminals 1a and 1d is equal at 2.4 volts. No current will flow through the feedback resistor Rf so the output voltage is 1.2 volts. This is the null condition of the circuit. If the gauge has an equivalent 20,000 micro-strain in tension R1 will be 129.6 Ohms, the voltage at terminals 1a and 1d will be 2.496 volts, the voltage across resistor R1 will be 1.248 volts which will give an out-of-balance current of 0.4 milliamps. If the gauge has an equivalent 20,000 micro-strain in compression R1 will be 110.4 Ohms, the voltage at terminals 1a and 1b will be 2.304 volts, the voltage across R1 will be 1.152 volts which will give an out-of-balance current of 0.4 milliamps in the reverse direction. If a linearity check is made for micro-strain against out-of-balance current it will show that micro-strain will be directly proportional to the out-of-balance current with negligible linearity error.

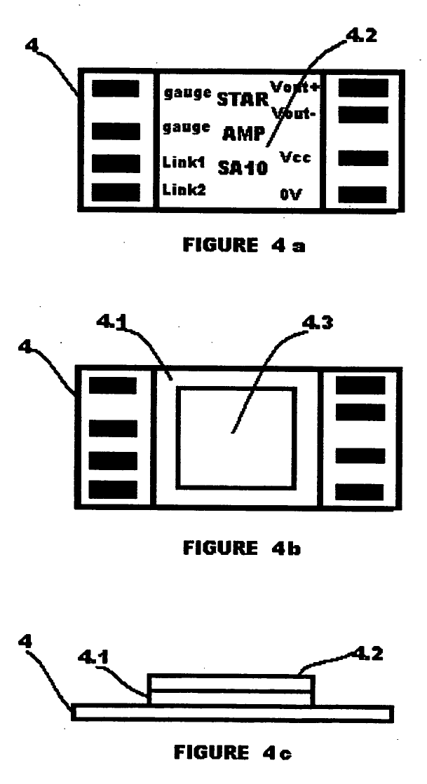

With reference to FIGS. 4a, 4b and 4c, FIG. 4a is a top plan view of a construction of a resistive element sensing circuit according to the present invention, FIG. 4b is also a top plan but with an encapsulation cap removed, and FIG. 4c is a side view. The construction of the circuit comprises three epoxy-glass laminate boards of preferably 1.6 mm in thickness, with a motherboard 4 having dimensions of preferably 37 mm×17 mm, but the motherboard could be as small as possible. The bottom side of the motherboard 4 is entirely copper and at the top side there are copper solder tags at each end for connections to the gauges (resistive sensing elements), voltage supply and the differential signal output. Components, preferably surface mount components, are mounted at the middle 4.3 of the board. Board 4.1 serves as a washer displacement board, while board 4.2 serves as a cap, the copper on the bottom of board 4.2 being connected to the copper on the bottom of board 4 to form a Faraday cage for EM immunity.

Various modifications and amplifications may occur to those skilled in the art without departing from the true spirit and scope of the principle of the invention as defined by the claims.

I claim:

1. A resistive sensing element circuit arrangement comprising:
first and second variable resistance sensing elements connected in series to form a resistive sensing element set having a first centre connection;
first and second fixed resistors connected in series and having a second centre connection;
a voltage supply having a positive voltage output connected to the free end of the first variable resistance sensing element and to the free end of the first fixed resistor and having a negative voltage output connected to the free end of the second variable resistance sensing element and to the free end of the second fixed resistor;
a differential amplifier having a positive input, a negative input and an output;
means connecting the first centre connection of the resistance sensing element set to the negative input of the differential amplifier;
means connecting the second centre connection of the series-connected fixed resistors to the positive input of the differential amplifier; and
a feedback resistor connected between the output and the negative input of the differential amplifier,
the arrangement being such that when the variable resistance sensing elements are inactive the voltage at the first centre connection of the first and second variable resistance sensing elements is set equal to the voltage at the positive input of the differential amplifier and when the variable resistance sensing elements are active the voltage at the output of the differential amplifier is proportional to an out-of-balance current that flows through the feedback resistor multiplied by the value of the feedback resistor.

2. A resistive sensing element circuit arrangement as claimed in claim 1 and including a plurality of sets of first and second variable resistance sensing elements connected to the first centre connection.

3. A resistive sensing element circuit arrangement as claimed in claim 1 and including a first further resistor connected in series between the positive voltage output of the voltage supply and the free end of the first variable resistance sensing element and a second further resistor connected between a point between the first further resistor and the free end of the first variable resistance sensing element and the output of the differential amplifier so as to provide a linearity correction when only the resistive sensing element connected to the positive voltage output of the voltage supply is active.

4. A resistive sensing element circuit arrangement as claimed in claim 1, wherein the circuit components other than the resistive sensing element set(s) and the voltage supply are encapsulated into an epoxy-glass laminate Faraday cage.

5. A resistive sensing element circuit arrangement as claimed in claim 1, wherein the variable resistance sensing elements are in the form of sensing elements that employ a change in resistance for measuring purposes.

6. A resistive sensing element circuit arrangement as claimed in claim 1, wherein the variable resistance sensing elements are in the form of strain gauges.

7. A resistive sensing element circuit arrangement as claimed in claim 1, wherein the values of the variable resistance sensing elements are substantially equal.

8. A resistive sensing element circuit arrangement as claimed in claim 1, wherein the values of the first and second fixed resistors are substantially equal.
